(19) United States
(12) Patent Application Publication
(10) Pub. No.: US 2016/0056095 A1
(43) Pub. Date: Feb. 25, 2016

(54) Leadframe Strip with Sawing Enhancement Feature

(71) Applicant: Infineon Technologies AG, Neubiberg (DE)

(72) Inventors: Lim Lay Yeap, Batu Berendam (MY); Tai Chiew Li, Melaka (MY); Yong Wae Chet, Melaka (MY); Tay Wee Boon, Melaka (MY); See Thiong Zhou, Batu Berendam (MY)

(21) Appl. No.: 14/467,229

(22) Filed: Aug. 25, 2014

(51) Int. Cl. H01L 23/495; H01L 21/48

(52) U.S. Cl. CPC H01L 23/49541; H01L 23/49579; H01L 23/49517; H01L 21/4828

(57) ABSTRACT

A leadframe strip includes a plurality of leads chemically etched into a metal sheet, a plurality of support structures chemically etched into the metal sheet, and a plurality of connecting structures chemically etched into the metal sheet. Each of the connecting structures is integrally connected at a first end to one of the leads and integrally connected at a second end to one of the support structures so that the leads are held in place by the support structures. The width of each connecting structure is at a minimum between the first and second ends of that connecting structure, increases from the minimum in a direction toward the first end, and increases from the minimum in a direction toward the second end. A method of manufacturing such a leadframe strip is also provided.

### TECHNICAL FIELD

The instant application relates to leadframe strips, and more particularly to leadframe strip sawing.

### BACKGROUND

A leadframe forms the base or skeleton of an IC package, providing mechanical support to semiconductor dies during assembly into a finished package. A leadframe typically includes a die paddle for attaching a semiconductor die, and leads providing the means for external electrical connection to the die. The die can be connected to the leads by wires, e.g. through wire bonding or tape automated bonds. Leadframes are typically constructed from flat sheet metal, e.g. by stamping or etching. The sheet metal is typically exposed to chemical etchants that remove areas not covered by photoresist. After the etching process, the etched frames are singulated (separated) into leadframe strips. Each leadframe strip includes a number of unit leadframes each having the die paddle and lead construction described above.

Semiconductor dies attached to the die paddles after completion of the assembly process of a leadframe strip, and tested before or after separation of the unit leadframes from the leadframe strip. The individual unit leadframes are separated from the leadframe strip often by sawing, whereby a saw blade cuts through metal support structures of the leadframe strip. The support structures are connected to and stabilize the leads and die paddles of the unit leadframes during the packaging process. The sawing process often causes metal smearing and burrs, which can electrically short adjacent leads. As such, it is desirable to have a leadframe strip design that is less susceptible to metal smearing and burrs during the sawing process.

### SUMMARY

According to an embodiment of a leadframe strip, the leadframe strip comprises a plurality of leads chemically etched into a metal sheet, a plurality of support structures chemically etched into the metal sheet, and a plurality of connecting structures chemically etched into the metal sheet. Each of the connecting structures is integrally connected at a first end to one of the leads and integrally connected at a second end to one of the support structures so that the leads are held in place by the support structures. The width of each connecting structure is at a minimum between the first and second ends of that connecting structure, increases from the minimum in a direction toward the first end, and increases from the minimum in a direction toward the second end.

According to an embodiment of a method of manufacturing a leadframe strip, the method comprises: chemically etching a plurality of leads into a metal sheet; chemically etching a plurality of support structures into the metal sheet; and chemically etching a plurality of connecting structures into the metal sheet, each of the connecting structures being integrally connected at a first end to one of the leads and integrally connected at a second end to one of the support structures so that the leads are held in place by the support structures. The width of each connecting structure is at a minimum between the first and second ends of that connecting structure, increases from the minimum in a direction toward the first end, and increases from the minimum in a direction toward the second end.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a partial top plan view of an embodiment of a leadframe strip having a sawing enhancement feature that reduces metal smearing and burrs during leadframe sawing.

FIG. 2, which includes FIGS. 2A through 2C, illustrates different exploded views of the leadframe strip shown in FIG. 1.

FIG. 3 illustrates a flow diagram of an embodiment of a method of manufacturing a leadframe strip that has a sawing enhancement feature for reducing metal smearing and burrs during leadframe sawing.

FIG. 4, which includes FIGS. 4A and 4B, illustrates an embodiment of transferring a geometric pattern of a leadframe strip having a sawing enhancement feature from a photomask to a photoresist on a metal sheet.

### DETAILED DESCRIPTION

According to embodiments described herein, a leadframe strip is provided with a sawing enhancement feature that reduces metal smearing and burrs during the leadframe sawing process. The sawing enhancement feature allows individual unit leadframes to be separated from the leadframe strip by sawing and with a significantly reduced likelihood of shorted leads caused by metal smearing and burrs.

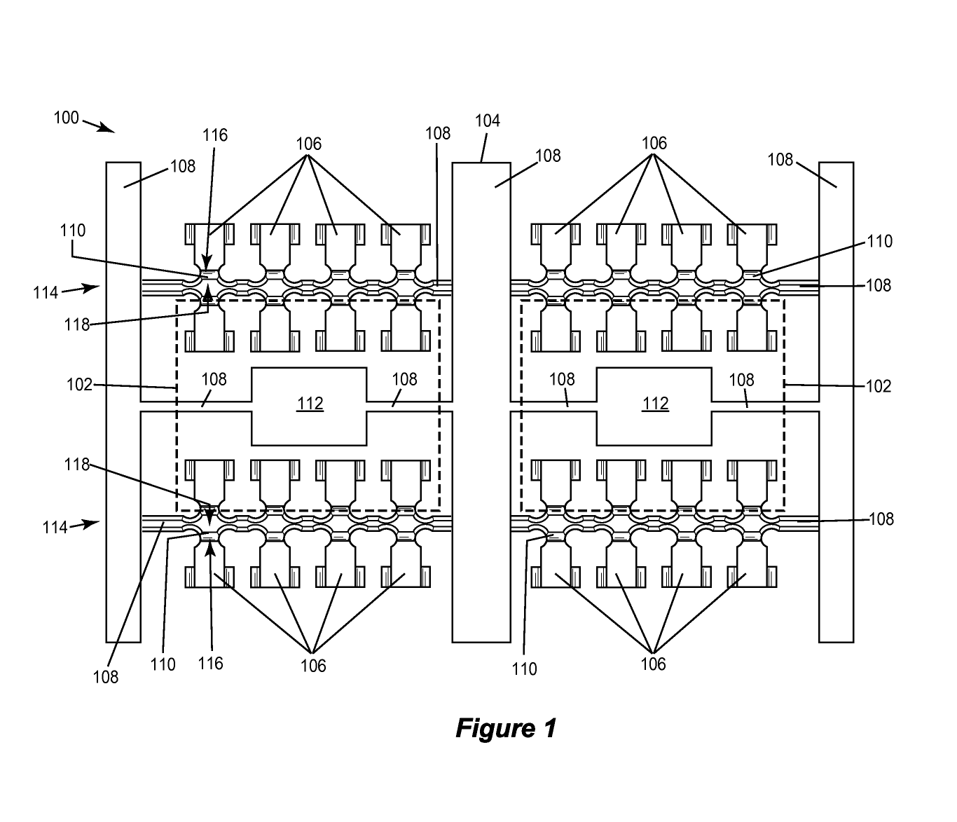

FIG. 1 illustrates a partial view of an embodiment of a leadframe strip 100 having a sawing enhancement feature that reduces metal smearing and burrs during the leadframe sawing process. The leadframe strip 100 includes a plurality of connected unit leadframes 102, two of which are shown completely in FIG. 1. The leadframe strip 100 is constructed from a chemically etched metal sheet 104 such as a copper sheet. The metal sheet 104 is exposed to chemical etchants that remove areas not covered by a photoresist, forming different structures of the lead frame strip 100. These structures include, but are not limited to, a plurality of leads 106 chemically etched into the metal sheet 104, a plurality of support structures 108 chemically etched into the metal sheet 104, and a plurality of connecting structures 110 chemically etched into the metal sheet 104. Optional die paddles 112 can also be chemically etched into the metal sheet 104. Semiconductor dies (not shown) can be attached the optional die paddles 112 during a subsequent die attach process. Alternatively, the semiconductor dies can be attached directly to the leads 106 of the corresponding unit leadframe 102 e.g. in a flip-chip configuration. The leads 106, support structures 108 and connecting structures 110 are integrally formed from the same metal sheet 104 by chemical etching as described in more detail later herein.

The support structures 110 are connected to and stabilize the leads 106 and optional die paddles 112 of the unit leadframes 102 during the packaging process. Final packages produced from the leadframe strip 100 do not include the support structures 110. A sawing process is used to cut through the support structures 110 and singulate (separate) the unit leadframes 102 after the packages are completed. Two sawing streets 114 are shown in FIG. 1. The sawing streets 114 correspond to regions of the leadframe strip 100 where a saw blade cuts through the support structures 108 as part of the unit leadframe singulation process.

The leads 106 are connected to some of the support structures 108 by the connecting structures 110. Each of the connecting structures 110 is integrally connected at a first end 116 to one of the leads 106 and integrally connected at a second end 118 to one of the support structures 108, so that the leads 106 are held in place by one of the support structures 108.

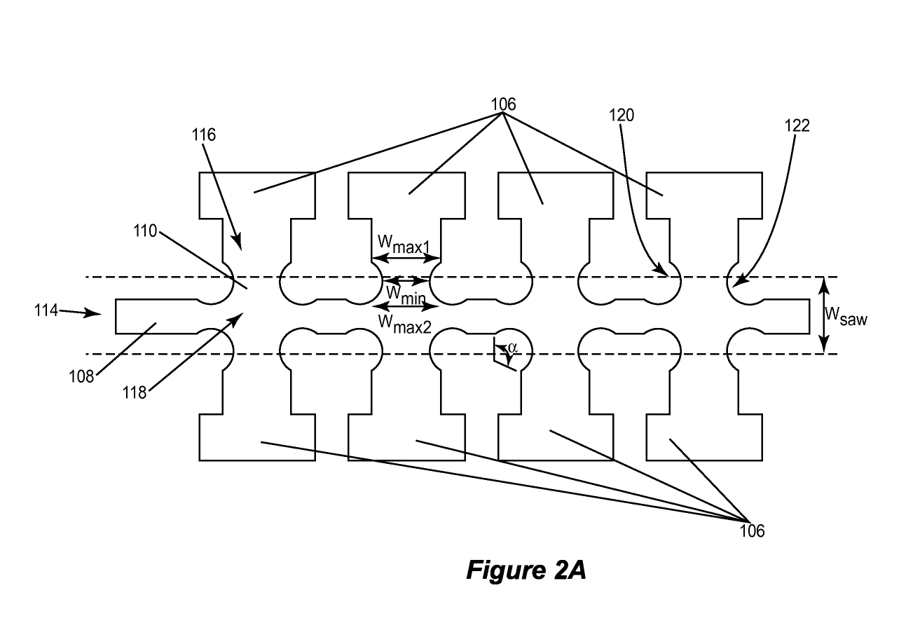

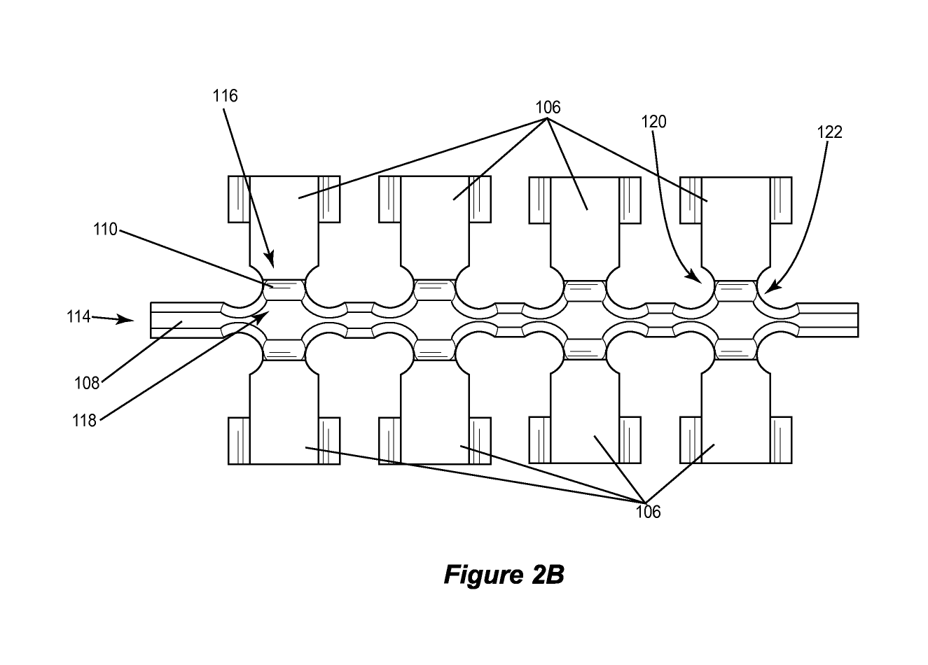

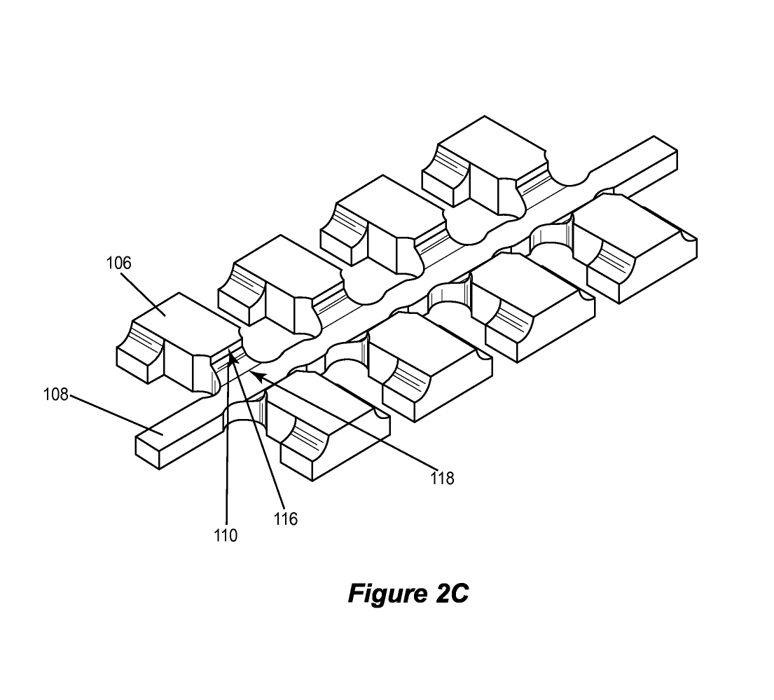

FIG. 2, which includes FIGS. 2A through 2C, illustrates a section of the leadframe strip and the sawing enhancement feature in more detail. FIG. 2A shows a top plan view of the leadframe strip section, FIG. 2B shows a bottom plan view of the leadframe strip section, and FIG. 2C shows a perspective view of the leadframe strip section.

The connecting structures 110 are designed with a sawing enhancement feature that reduces metal smearing and burrs during the sawing process. According to one embodiment, the sawing enhancement feature corresponds to a varying width of the connecting structures 110.

More particularly, the width of each connecting structure 110 is at a minimum (Wₘᵢₙ) between the first and second ends 116, 118 of that connecting structure 110, increases from the minimum to a first maximum (Wₘₐₓ₁) in a direction toward the first end 116, and increases from the minimum to a second maximum (Wₘₐₓ₂) in a direction toward the second end 118. The sawing streets 114 have a define width (W_{saw}) corresponding to the thickness of the saw blade, and align at or near the minimum width of the corresponding connecting structures 110. This way, the saw blade cuts through less metal in the region of the connecting structures 110, which in turn reduces metal smearing and burrs near the distal end of the leads 106. The proximal end of each lead 106 is disposed at a more interior position within the unit leadframes 102 than the distal ends.

In one embodiment, each of the connecting structures 110 has opposing curved sidewalls 120, 122. The distance between the opposing curved sidewalls 120, 122 of each connecting structure 110 defines the width of that connecting structure 110. The width varies between the first and second ends 116, 118 of the connecting structures 110 as previously described herein. The opposing curved sidewalls 120, 122 can be formed from intentional undercuts designed into the floorplan (layout/design) of the leadframe strip 100, and chemically etched into the metal sheet 104 as part of the connecting structures 110. Each of the opposing curved sidewalls 120, 122 can form an arc i.e. part of the circumference of a circle or other curve.

One measure of an arc is the angle (α) formed by the arc at the center of the circle or curve that the arc is part of. The other measure of an arc is the length of the arc. In some embodiments, the angle α formed by each of the arcs is greater than 90 degrees and less than 180 degrees. The arcs for at least some of the connecting structures 110 can be of the same length as shown in FIG. 2. Some or all of the arcs can extend into the adjacent integrally connected support structure 108 also as shown in FIG. 2. The desired sidewall curvature, arc length and arc angle of the connecting structures 110 can be designed into the floorplan (layout/design) for the leadframe strip 100, so that the connecting structures 110 are etched with a particular sidewall curvature, arc length and arc angle that are suitable for reducing metal smearing and burrs during the leadframe sawing process.

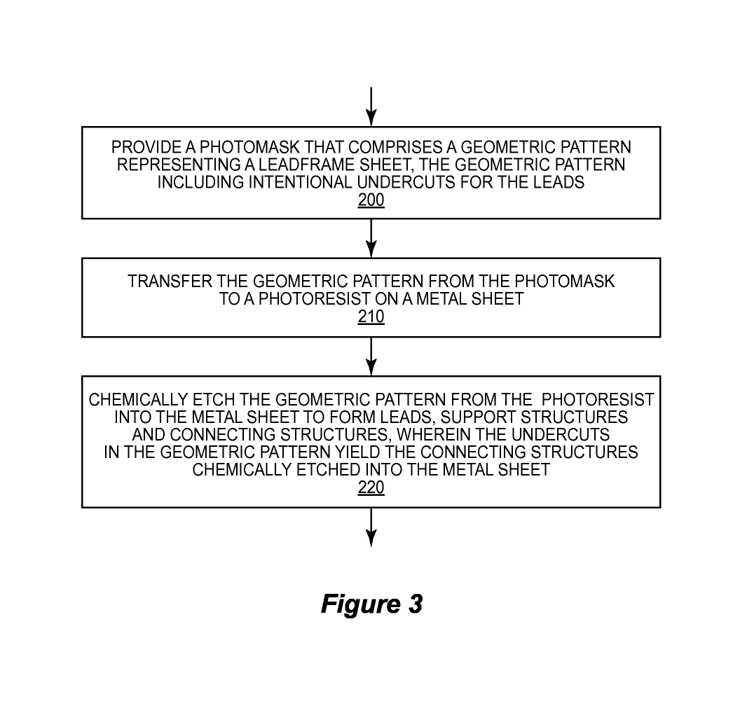

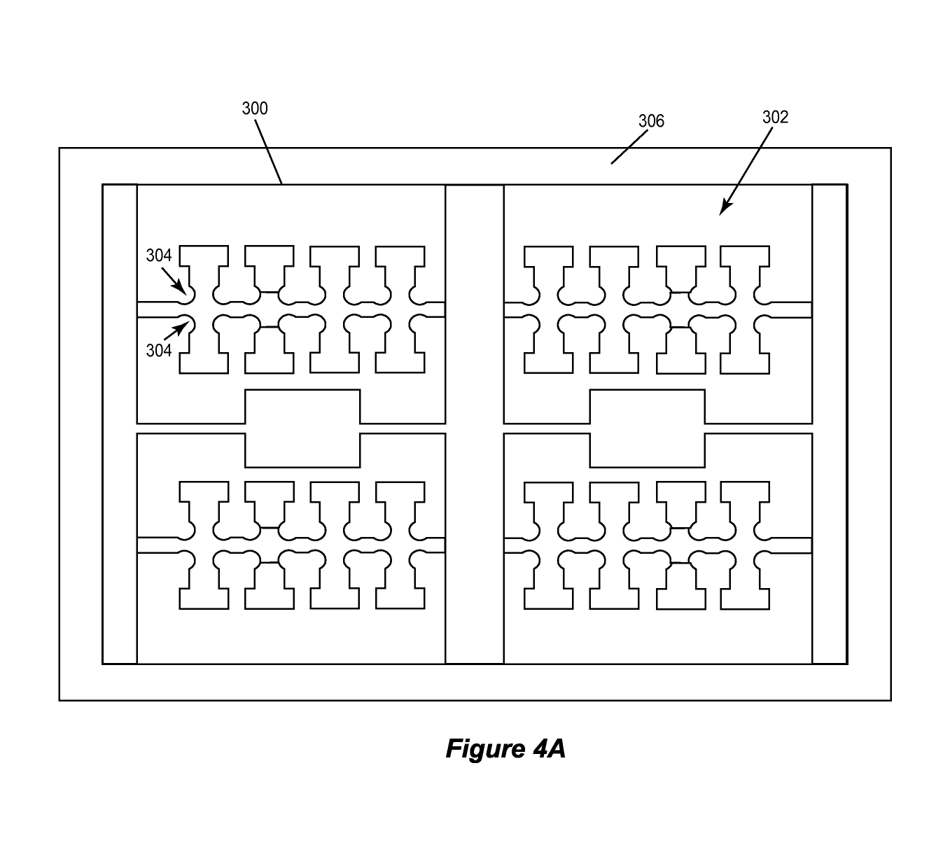

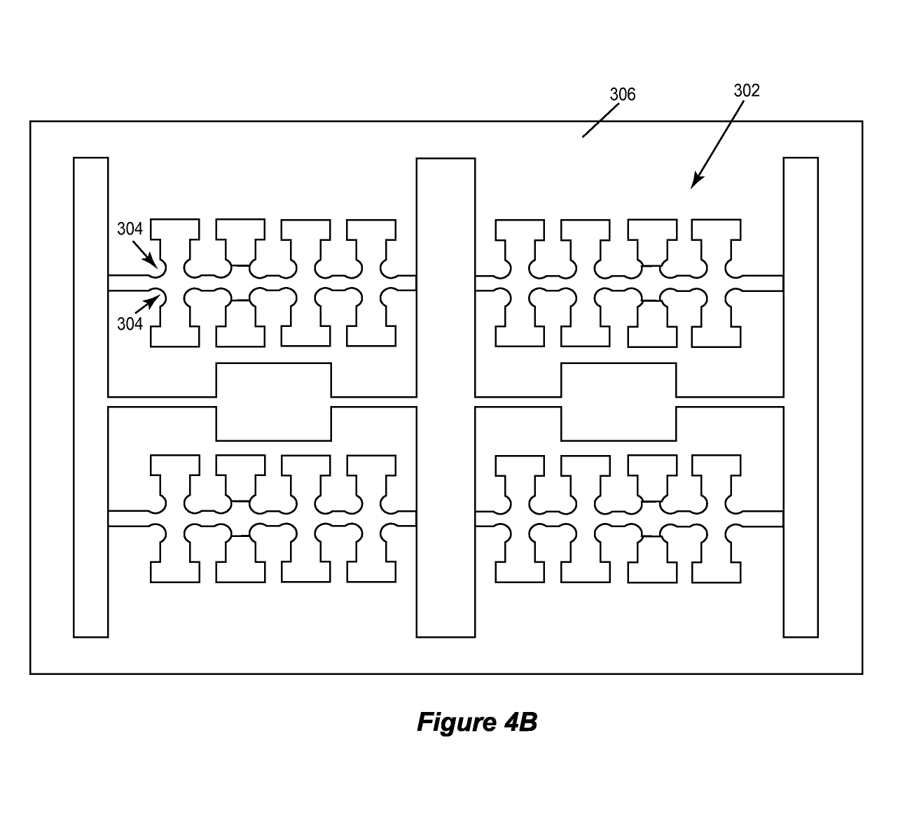

FIG. 3 illustrates an embodiment of designing and manufacturing a leadframe strip having a sawing enhancement feature that reduces metal smearing and burrs during the leadframe sawing process. FIG. 3 is described next in conjunction with FIG. 4, which includes FIGS. 4A and 4B. According to this embodiment, a photomask 300 is provided that comprises a geometric pattern 302 representing the leadframe strip, the geometric pattern 302 including intentional undercuts 304 for the leads (FIG. 3, Block 200). The undercuts 304 are intentionally designed into the floorplan/layout of the leadframe strip as part of the leadframe strip design process. The leadframe design is transferred to the photomask 300. FIG. 4A shows the photomask 300 aligned with a photoresist 306 on a metal sheet (out of view).

The geometric pattern 302 is then transferred from the photomask 300 to the photoresist 306 on the metal sheet (FIG. 3, Block 210). For example, light or another energy source can be used to transfer the geometric pattern 302 from the photomask 300 to a light-sensitive chemical photoresist 306. FIG. 4B shows the photoresist 306 after photoresist imaging and removal of the photomask 300. The geometric pattern 302 transferred to the photoresist 306 is then etched into the underlying metal sheet using any standard chemical etching process to form the leads, the support structures and the connecting structures of the leadframe strip (FIG. 3, Block 220). One example of a resulting leadframe strip 100 is shown in FIG. 1.

The undercuts 302 intentionally designed into the geometric pattern 302 of the leadframe strip floorplan/layout are chemically etched into the metal sheet, yielding connecting structures 110 having a sawing enhancement feature that reduces metal smearing and burrs during the sawing process as previously described herein. The sawing enhancement feature corresponds to the varying width of the connecting structures 110 provided by the undercuts 302. More particularly, the width of each connecting structure 110 is at a minimum between the first and second ends 116, 118 of that connecting structure 110, increases from the minimum in a direction toward the first end 116, and increases from the minimum in a direction toward the second end 118 due to the undercuts 302 intentionally designed into the geometric pattern 302 of the leadframe strip floorplan/layout. The undercuts 304 correspond to the portion of the metal sheet that is etched away under the photoresist 306. The undercuts 302 are chemically etched into the metal sheet by controlling various etching parameters such as chemical concentration of the etchant, chemical spraying pressure, material feeding rate, etc.

The undercuts 302 result in the connecting structures 110 having opposing curved sidewalls 120, 122. The distance between the opposing curved sidewalls 120, 122 of each connecting structure 110 defines the width of that connecting structure 110, which varies between the first and second ends 116, 118 of each connecting structure 110 as described above. The opposing curved sidewalls 120, 122 can form an arc, and the angle formed by each of the arcs can be greater than 90 degrees and less than 180 degrees as previously described herein. The arcs for at least some of the connecting structures 110 can be of the same length, and some or all of the arcs can extend into the adjacent integrally connected support structure 108 also as previously described herein.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

1. A leadframe strip, comprising:
a plurality of leads chemically etched into a metal sheet;
a plurality of support structures chemically etched into the metal sheet; and
a plurality of connecting structures chemically etched into the metal sheet,
wherein each of the connecting structures is integrally connected at a first end to one of the leads and integrally connected at a second end to one of the support structures so that the leads are held in place by the support structures,
wherein the width of each connecting structure is at a minimum between the first and second ends of that connecting structure, increases from the minimum in a direction toward the first end, and increases from the minimum in a direction toward the second end.

2. The leadframe strip of claim 1, wherein each of the connecting structures has opposing curved sidewalls, and wherein the distance between the opposing curved sidewalls of each connecting structure defines the width of that connecting structure.

3. The leadframe strip of claim 2, wherein the opposing curved sidewalls are formed from undercuts chemically etched into the metal sheet.

4. The leadframe strip of claim 2, wherein each of the opposing curved sidewalls forms an arc, and wherein the angle formed by each of the arcs is greater than 90 degrees and less than 180 degrees.

5. The leadframe strip of claim 2, wherein each of the opposing curved sidewalls forms an arc, and wherein the arcs for at least some of the connecting structures are of the same length.

6. The leadframe strip of claim 2, wherein each of the opposing curved sidewalls forms an arc that extends into the adjacent integrally connected support structure.

7. The leadframe strip of claim 1, wherein the metal sheet is a copper sheet.

8. A method of manufacturing a leadframe strip, the method comprising:
chemically etching a plurality of leads into a metal sheet;
chemically etching a plurality of support structures into the metal sheet; and
chemically etching a plurality of connecting structures into the metal sheet, each of the connecting structures being integrally connected at a first end to one of the leads and integrally connected at a second end to one of the support structures so that the leads are held in place by the support structures,
wherein the width of each connecting structure is at a minimum between the first and second ends of that connecting structure, increases from the minimum in a direction toward the first end, and increases from the minimum in a direction toward the second end.

9. The method of claim 8, wherein chemically etching the leads, the support structures and the connecting structures into the metal sheet comprises:
providing a photomask that comprises a geometric pattern representing the leadframe strip, the geometric pattern including intentional undercuts for the leads;
transferring the geometric pattern from the photomask to a photoresist on the metal sheet; and
chemically etching the geometric pattern from the photoresist into the metal sheet to form the leads, the support structures and the connecting structures,
wherein the undercuts in the geometric pattern yield the connecting structures chemically etched into the metal sheet.

10. The method of claim 8, wherein each of the connecting structures has opposing curved sidewalls, and wherein the distance between the opposing curved sidewalls of each connecting structure defines the width of that connecting structure.

11. The method of claim 10, wherein the opposing curved sidewalls are formed from undercuts chemically etched into the metal sheet.

12. The method of claim 10, wherein each of the opposing curved sidewalls forms an arc, and wherein the angle formed by each of the arcs is greater than 90 degrees and less than 180 degrees.

13. The method of claim 10, wherein each of the opposing curved sidewalls forms an arc, and wherein the arcs for at least some of the connecting structures are of the same length.

14. The method of claim 10, wherein each of the opposing curved sidewalls forms an arc that extends into the adjacent integrally connected support structure.

15. The method of claim 8, wherein the metal sheet is a copper sheet.

16. The method of claim 8, further comprising singulating individual unit leadframes from the leadframe strip by sawing through at least one of the support structures and at least a portion of at least one of the connecting structures.

17. A leadframe strip, comprising:
a plurality of leads etched into a metal sheet;
a plurality of support structures etched into the metal sheet;
a plurality of connecting structures etched into the metal sheet, each of the connecting structures having a first end that adjoins one of the leads and a second end that adjoins one of the support structures so that the leads are held in place by the support structures via the connecting structures; and
a plurality of sawing streets corresponding to different regions of the leadframe strip to be cut through so as to form individual unit leadframes, wherein each of the sawing streets comprises one of the support structures and at least a portion of the connecting structures adjoining that support structure,
wherein the width of each connecting structure is at a minimum between the first and second ends of that connecting structure, increases from the minimum in a direction toward the first end, and increases from the minimum in a direction toward the second end.
